(19) United States
(12) Patent Application Publication
(10) Pub. No.: US 2022/0055261 A1
(43) Pub. Date: Feb. 24, 2022

(54) RESIN MOLDING APPARATUS AND MANUFACTURING METHOD OF RESIN MOLDED PRODUCT

(71) Applicant: TOWA Corporation, Kyoto (JP)

(72) Inventors: Hayato YASUI, Kyoto (JP); Yohei ONISHI, Kyoto (JP)

(73) Assignee: TOWA Corporation, Kyoto (JP)

(21) Appl. No.: 17/402,627

(22) Filed: Aug. 16, 2021

(30) Foreign Application Priority Data
Aug. 18, 2020 (JP) 2020-138132

(51) Int. Cl. B29C 43/40; B29C 43/50; B29C 43/34

(52) U.S. Cl. CPC B29C 43/40; B29L 2031/34; B29C 43/34; B29C 43/50

(57) ABSTRACT

A resin molding apparatus capable of suppressing an occurrence of defects related to resin filling. The resin molding apparatus includes: a molding mold which forms a cavity; a pot which is arranged in the molding mold and is capable of accommodating a resin material, and in which an opening portion opening directly to the cavity is formed; and a plunger which is arranged to be slidable in the pot, and transfers the resin material accommodated in the pot toward the cavity via the opening portion by extruding the resin material. An inner diameter of the opening portion is formed to be the same as an outer diameter of the plunger or larger than the outer diameter of the plunger.

### CROSS-REFERENCE TO RELATED APPLICATION

This application claims the priority benefit of Japan application serial no. 2020-138132, filed on Aug. 18, 2020. The entirety of the above-mentioned patent application is hereby incorporated by reference herein and made a part of this specification.

### BACKGROUND

### Technical Field

The disclosure relates to a technique of a resin molding apparatus and a manufacturing method of a resin molded product.

### Related Art

Patent literature 1 discloses a resin molding apparatus capable of revealing a semiconductor chip and performing resin molding. In this resin molding apparatus, a workpiece held on an upper surface of a carrier plate is clamped by an upper mold and a lower mold. A penetration hole having a tapered shape is formed in the carrier plate. By pushing up a melted mold resin in a pot arranged in the lower mold with a plunger, the mold resin is filled into an upper mold cavity which is formed on an opposite side (an upper side) of the carrier plate through the penetration hole of the carrier plate, and the resin molding is performed. At this time, a lower surface of a semiconductor chip arranged in the workpiece is sticked to the upper surface of the carrier plate by a sticking sheet. Thereby, a resin molded product in which a lower surface of the semiconductor chip is revealed can be obtained.

### LITERATURE OF RELATED ART

### Patent Literature

[Patent literature 1] Japanese Patent Laid-Open No. 2017-37947

### SUMMARY

However, in the resin molding apparatus disclosed in Patent literature 1, because the resin is supplied into the upper mold cavity from the penetration hole formed in a tapered shape, a flow path of the resin is narrow, and the filling of the resin into the upper mold cavity is difficult. Particularly, in a case where the size of an object to be molded is large or in other cases, a flow distance of the resin is also increased, and thus the filling of the resin into the upper mold cavity may not go well, and defects such as voids, unfilling, and the like may occur.

A problem to be solved by the disclosure is to provide a resin molding apparatus and a manufacturing method of a resin molded product capable of suppressing an occurrence of defects related to resin filling.

The problem to be solved by the disclosure is described as above, and in order to solve the problem, a resin molding apparatus according to the disclosure includes: a molding mold which forms a cavity; a pot which is arranged in the molding mold and is capable of accommodating a resin material, and in which an opening portion opening directly to the cavity is formed; and a plunger which is arranged to be slidable in the pot, and transfers a resin material accommodated in the pot toward the cavity via the opening portion by extruding the resin material. An inner diameter of the opening portion is formed to be the same as an outer diameter of the plunger or larger than the outer diameter of the plunger.

In addition, a manufacturing method of a resin molded product according to the disclosure is for manufacturing a resin molded product by using the resin molding apparatus.

In addition, a manufacturing method of a resin molded product according to the disclosure includes: a mold clamping step, in which mold clamping is performed on a molding mold forming a cavity after a substrate is conveyed to the molding mold and a resin material is conveyed to a pot in which an opening portion opening directly to the cavity is formed; and a transfer step, in which a resin material accommodated in the pot is transferred toward the cavity via the opening portion by extruding the resin material with a plunger after the mold clamping step. In the transfer step, the resin material is transferred via the opening portion having an inner diameter which is the same as an outer diameter of the plunger or larger than the outer diameter of the plunger.

According to the disclosure, an occurrence of defects related to resin filling can be suppressed.

### BRIEF DESCRIPTION OF THE DRAWINGS

(a) of FIG. 1 is a diagram of a substrate to be resin-sealed as viewed from a surface side, and (b) of FIG. 1 is a perspective view showing the substrate.

FIG. 2 is a side cross-sectional view showing an entire configuration of a resin molding apparatus according to a first embodiment.

FIG. 3 is a cross-sectional perspective view showing a lower part of the resin molding apparatus according to the first embodiment.

FIG. 4 is an enlarged side cross-sectional view of the lower part of the resin molding apparatus according to the first embodiment.

FIG. 5 is a flowchart showing a manufacturing method of a resin molded product.

FIG. 6 is a side cross-sectional view of the resin molding apparatus for describing a preparation step, a film arrangement step, and a carrying-in step.

FIG. 7 is a side cross-sectional view of the resin molding apparatus for describing a mold clamping step.

FIG. 8 is a side cross-sectional view of the resin molding apparatus for describing a transfer step.

FIG. 9 is a side cross-sectional view of the resin molding apparatus for describing a mold opening step and a carrying-out step.

FIG. 10 is a side cross-sectional view of the resin molding apparatus for describing a post-treatment step.

(a) of FIG. 11 is an enlarged side cross-sectional view showing a resin molding apparatus according to a second embodiment, (b) of FIG. 11 is a perspective view showing a pressing member, and (c) of FIG. 11 is a plan view showing the pressing member.

### DESCRIPTION OF THE EMBODIMENTS

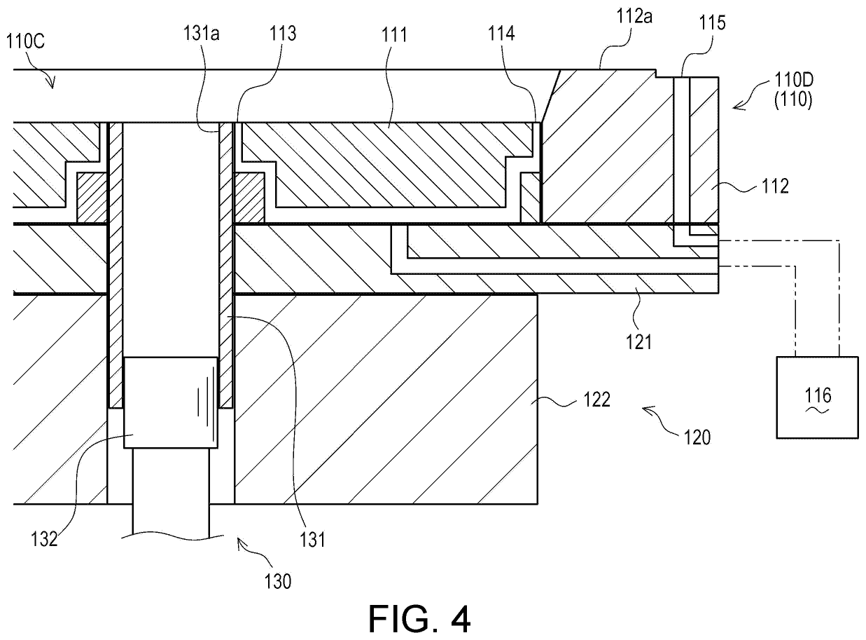

A resin molding apparatus 100 according to a first embodiment of the disclosure is described below with reference to FIGS. 1 to 4. Note that, drawings used in the following description are for conceptually describing a configuration of the resin molding apparatus 100, and for convenience of description, the dimension and the like of each part may be exaggerated, or the shape and the like of members may be appropriately simplified.

The resin molding apparatus 100 resin-seals electronic components such as semiconductor chips 11 and the like arranged on a surface 10a of a substrate 10, and manufactures a resin molded product.

First, the substrate 10 to be resin-sealed by the resin molding apparatus 100 is described.

As shown in FIG. 1, the substrate 10 is formed in a circular flat plate shape. A plurality of semiconductor chips 11 formed in a rectangular flat plate shape are arranged on the surface 10a of the substrate 10 at an appropriate pitch.

Additionally, as the substrate 10, a semiconductor substrate such as a silicon wafer or the like, a lead frame, a printed wiring substrate, a metal substrate, a resin substrate, a glass substrate, a ceramic substrate, or the like can be used. In addition, the substrate 10 may be a carrier used in fan out wafer level packaging (FOWLP) and fan out panel level packaging (FOPLP).

In addition, a mold release layer 12 having a circular shape is formed at the center of the surface 10a of the substrate 10. The mold release layer 12 is used for preventing a resin R described later from adhering to the surface 10a of the substrate 10, and facilitating the removal of the resin R from the substrate 10. As the mold release layer 12, for example, a film (a mold release film) obtained by performing silicon coating or the like on a relatively thin plate-like (film-like) member to give mold releasability can be used. The mold release layer 12 is pasted on the surface 10a of the substrate 10 by using an appropriate adhesive.

Next, a specific configuration of the resin molding apparatus 100 is described.

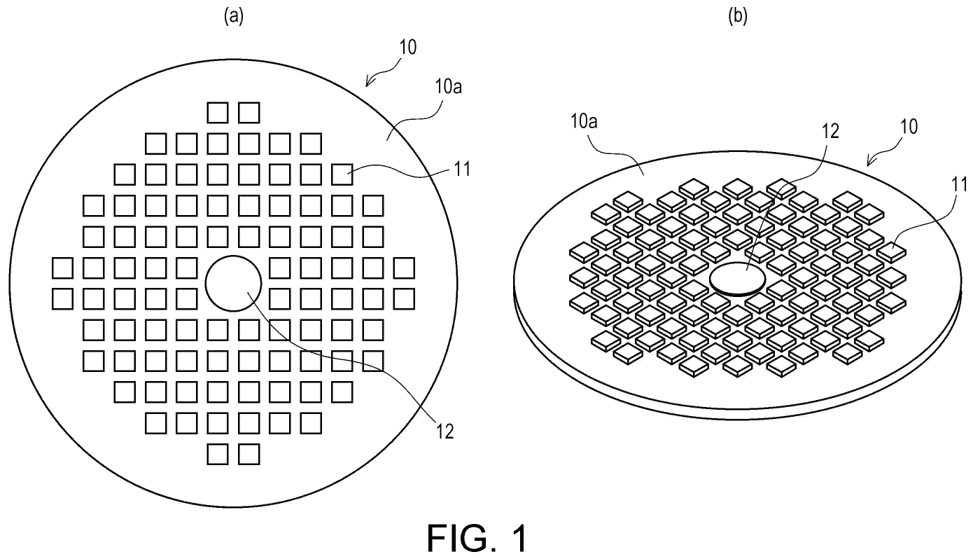

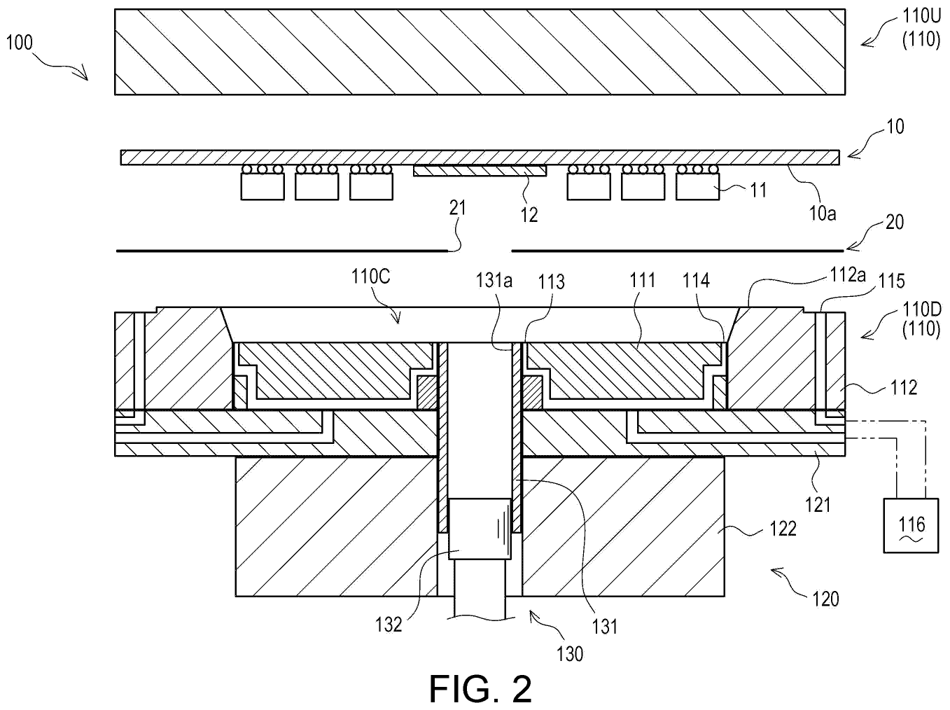

The resin molding apparatus 100 shown in FIGS. 2 to 4 mainly includes a molding mold 110 (a lower mold 110D and an upper mold 110U), a mold clamping mechanism 120, a resin injection mechanism 130, and the like.

The molding mold 110 is configured from the lower mold 110D and the upper mold 110U, and forms a cavity 110C for molding the resin R.

The lower mold 110D mainly includes a bottom surface member 111, a side surface member 112, and the like.

The bottom surface member 111 forms a bottom surface of the cavity 110C. The bottom surface member 111 is formed in a circular shape in a plan view. The bottom surface member 111 is formed to have an appropriate vertical width.

The side surface member 112 forms a side surface of the cavity 110C. The side surface member 112 is formed in a cylindrical shape surrounding the bottom surface member 111 from the outside. A vertical width of the side surface member 112 is formed to be larger than the vertical width of the bottom surface member 111. The side surface member 112 is arranged to be fitted to an outer peripheral surface of the bottom surface member 111. The side surface member 112 is arranged in a state of being placed on an upper surface of a base plate 121 described later together with the bottom surface member 111. An upper surface of the side surface member 112 is located above an upper surface of the bottom surface member 111. In this way, the cavity 110C is formed, which is surrounded by the bottom surface member 111 and the side surface member 112 and has a circular shape in a plan view. A contact surface 112a and an air discharge groove 112b are formed in the side surface member 112.

The contact surface 112a is a plane which is formed on the upper surface of the side surface member 112 and has an annular shape in a plan view. The contact surface 112a is formed at the highest position on the upper surface of the side surface member 112.

The air discharge groove 112b is used for discharging air in the cavity 110C to the exterior of the cavity 110C. The air discharge groove 112b is formed by slightly recessing the contact surface 112a. The air discharge groove 112b is formed to connect an inner periphery and an outer periphery of the contact surface 112a. A plurality of air discharge grooves 112b are radially formed centering on one point (the center of the contact surface 112a). Note that, the air discharge groove 112b is an embodiment of the air discharge portion according to the disclosure.

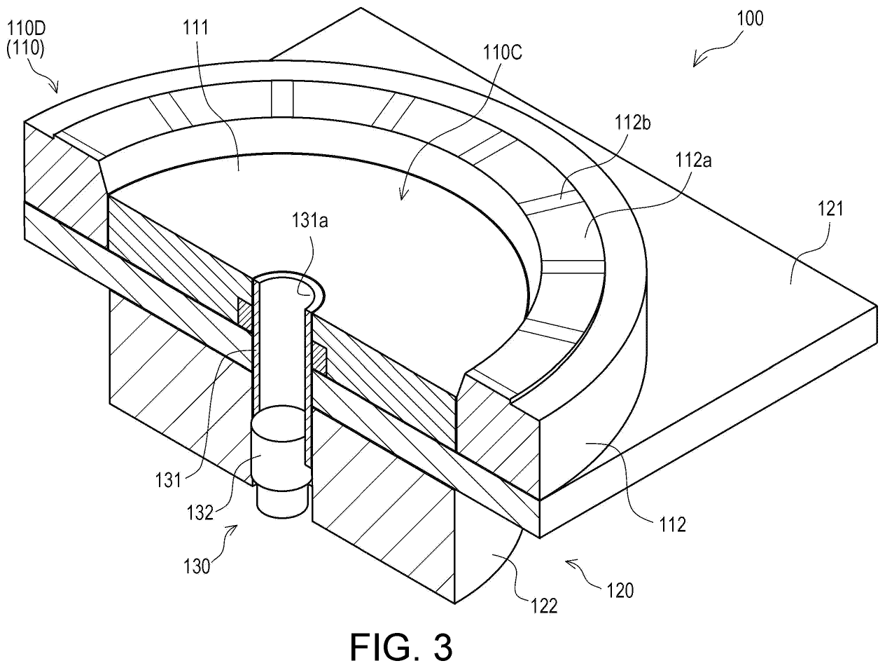

In addition, the lower mold 110D includes suction portions (a first suction portion 113, a second suction portion 114, and a third suction portion 115). The suction portions suck the mold release film 20 (see FIG. 2) used during resin molding to the molding mold 110 (the lower mold 110D). Note that, in FIG. 3, the suction portions are not shown for simplification.

The first suction portion 113 is an opening portion formed to open on the upper surface of the bottom surface member 111. The first suction portion 113 is formed in the vicinity of the central part of the bottom surface member 111 just on the outer side of a pot 131 (at a position adjacent to the pot 131). Note that, the first suction portion 113 is an embodiment of the suction portion according to the disclosure.

The second suction portion 114 is an opening portion formed to open on the upper surface of the bottom surface member 111. The second suction portion 114 is formed in the vicinity of the outer peripheral part of the bottom surface member 111 just on the inner side of the side surface member 112 (at a position adjacent to the side surface member 112).

The third suction portion 115 is an opening portion formed to open on the upper surface of the side surface member 112. The third suction portion 115 is formed on the outer side of the contact surface 112a.

Additionally, although not shown, the first suction portion 113, the second suction portion 114, and the third suction portion 115 may be respectively formed in an annular groove shape surrounding the center of the cavity 110C, or a plurality of the first suction portions 113, the second suction portions 114, and the third suction portions 115 may be formed to be scattered on the periphery surrounding the center of the cavity 110C.

The first suction portion 113, the second suction portion 114, and the third suction portion 115 can be brought to negative pressure by a vacuum pump 116. The vacuum pump 116 is connected to the first suction portion 113 and the like via communication holes appropriately formed in the lower mold 110D and the base plate 121.

The upper mold 110U shown in FIG. 2 can hold the substrate 10. The upper mold 110U is formed to have an appropriate vertical width. A suction hole (not shown) for sucking and holding the substrate 10 is appropriately formed on a bottom surface of the upper mold 110U.

The substrate 10 can be sucked and held by bringing the suction hole to negative pressure by a vacuum pump or the like (not shown). Besides, an end portion of the substrate 10 is mechanically held by a claw portion (not shown) attached to the upper mold 110U side.

The mold clamping mechanism 120 shown in FIGS. 2 to 4 mainly includes the base plate 121, a support portion 122, a fixing portion (not shown), an elevating mechanism (not shown), and the like.

The base plate 121 holds the lower mold 110D. The bottom surface member 111 and the side surface member 112 of the lower mold 110D are appropriately fixed to the upper surface of the base plate 121.

The support portion 122 supports the base plate 121 and is arranged in a way that it can be raised and lowered vertically. The base plate 121 is appropriately fixed to an upper surface of the support portion 122. The support portion 122 is arranged in a way that it can be raised and lowered vertically along a plurality of guide members (not shown).

The fixing portion (not shown) holds the upper mold 110U above the lower mold 110D. The upper mold 110U is fixed to a lower surface of the fixing portion (not shown) via an appropriate member.

The elevating mechanism (not shown) is used for raising and lowering the support portion 122. As the elevating mechanism (not shown), a ball screw mechanism, a hydraulic cylinder, a toggle mechanism, or the like can be used.

The resin injection mechanism 130 shown in FIGS. 2 to 4 injects the resin R to the cavity 110C. The resin injection mechanism 130 mainly includes the pot 131, a plunger 132, and the like.

The pot 131 accommodates a resin material (a tablet resin 30 described later) used for resin sealing. The pot 131 is formed in a cylindrical shape. The pot 131 has a constant inner diameter along an axial direction. The pot 131 is arranged to vertically penetrate the bottom surface member 111, the base plate 121, and the support portion 122 in a state in which the axial direction is oriented vertically. The pot 131 is arranged at the central part of the bottom surface member 111 (the cavity 110C). An upper end of the pot 131 is arranged at substantially the same height as the upper surface of the bottom surface member 111. In this way, an opening portion 131a on the upper end side of the pot 131 is arranged to open directly to the cavity 110C.

Note that, the fact that the pot 131 (the opening portion 131a) opens directly to the cavity 110C means that no other member that narrows a flow path of the resin R is arranged between the pot 131 and the cavity 110C.

In the embodiment, an example is shown in which no other member is arranged between the pot 131 and the cavity 110C, but it can also be said that the pot 131 opens directly to the cavity 110C when other members having a shape that does not narrow the flow path of the resin R (does not hinder the flow of the resin R) are arranged. For example, a tubular spacer or the like having the same inner diameter as the pot 131 may be arranged on an upper part of the pot 131.

The plunger 132 transfers a tablet-shaped resin material (the tablet resin 30) accommodated in the pot 131 toward the cavity 110C. The plunger 132 is formed in a columnar shape having an outer diameter substantially the same as an inner diameter of the pot 131. Note that, strictly speaking, the plunger 132 has an outer diameter slightly smaller than the inner diameter of the pot 131 to an extent of being slidable in the pot 131. The plunger 132 is arranged on the inner side of the pot 131 to be slidable along the axial direction of the pot 131.

The plunger 132 is connected to an actuator (for example, a ball screw, a motor, or the like) via an appropriate member. The plunger 132 can be raised and lowered vertically (in the axial direction of the pot 131) by a drive force of this actuator.

Additionally, an action of each portion of the resin molding apparatus 100 described above is appropriately controlled by a control device (not shown).

Next, a manufacturing method of a resin molded product using the resin molding apparatus 100 configured as above is described.

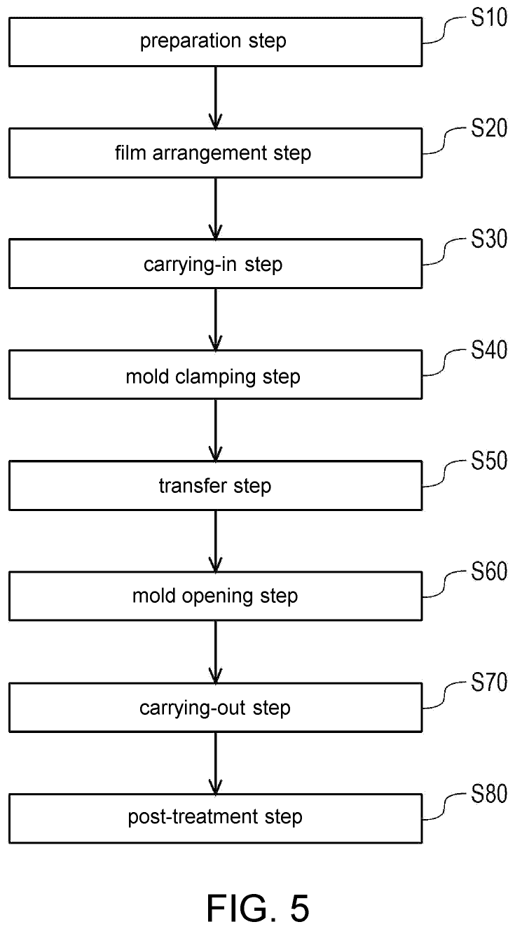

As shown in FIG. 5, the manufacturing method of a resin molded product according to the embodiment mainly includes a preparation step S10, a film arrangement step S20, a carrying-in step S30, a mold clamping step S40, a transfer step S50, a mold opening step S60, a carrying-out step S70, and a post-treatment step S80. Hereinafter, these steps are described in order.

The preparation step S10 is a step of preparing the substrate 10 and the tablet resin 30 used in resin molding. Note that, the preparation step S10 is an embodiment of the mold release layer forming step according to the disclosure.

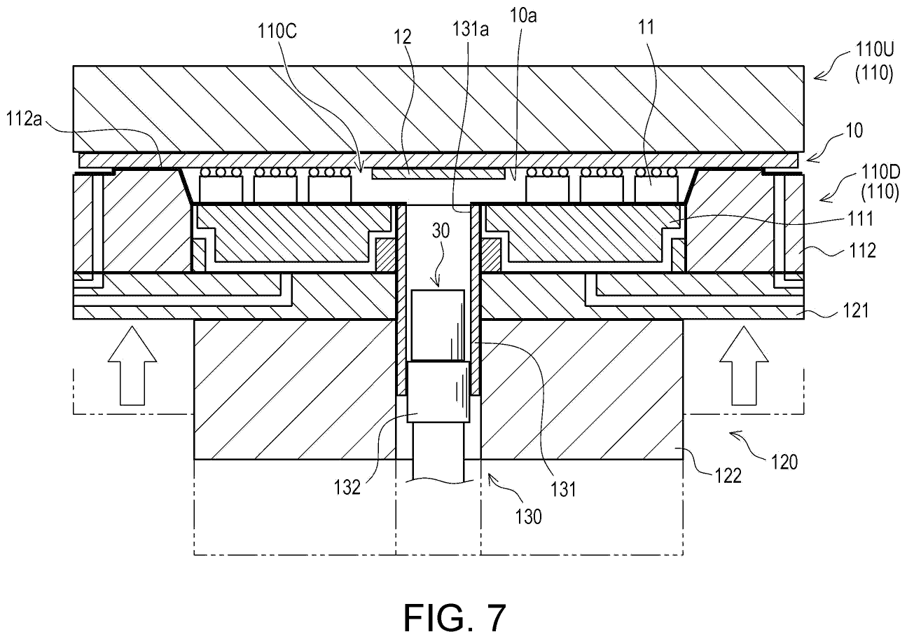

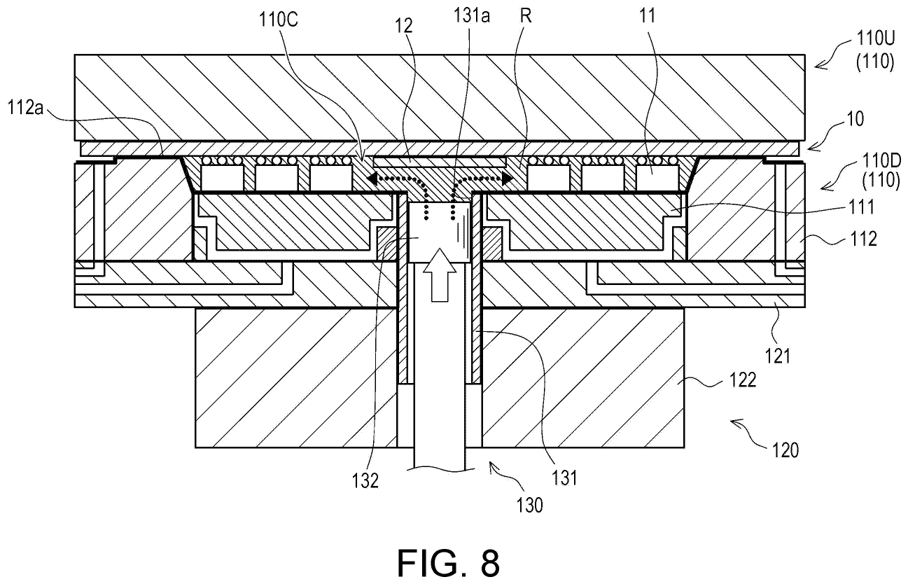

Specifically, in the preparation step S10, the mold release layer 12 is formed on the substrate 10 on which the semiconductor chip 11 is arranged (see FIG. 1). For example, the mold release layer 12 is formed on the substrate 10 by pasting a circular mold release film at the center of the surface 10a of the substrate 10. The mold release layer 12 is formed in a part facing the opening portion 131a of the pot 131 (for example, as shown in FIG. 7, directly above the opening portion 131a).

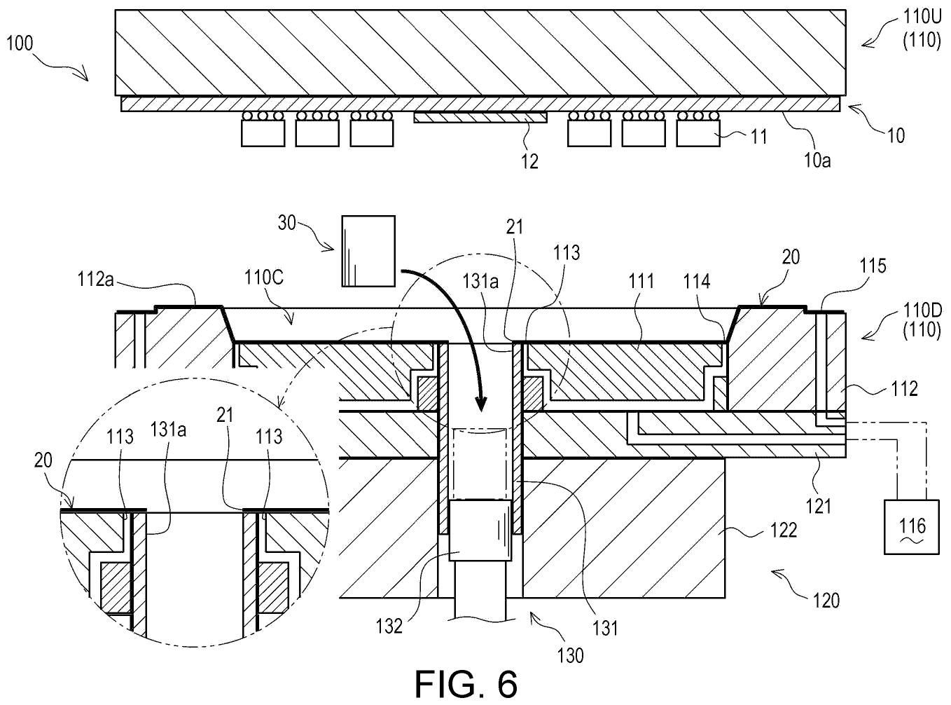

In addition, the tablet resin 30 is formed in a predetermined shape (in the embodiment, a columnar shape) in advance. An outer diameter of the tablet resin 30 is formed to be slightly smaller than the inner diameter of the pot 131 (see FIG. 6). The substrate 10 on which the mold release layer 12 is formed and the tablet resin 30 are arranged at predetermined locations in preparation for carrying in.

After the substrate 10 and the tablet resin 30 are prepared, the process proceeds from the preparation step S10 to the film arrangement step S20.

The film arrangement step S20 is a step of arranging the mold release film 20 in the lower mold 110D.

Specifically, in the film arrangement step S20, the mold release film 20 is carried into the molding mold 110 by a predetermined conveyance device. As shown in FIG. 2, the mold release film 20 is formed to have a shape and a size to such an extent that substantially the entire lower mold 110D (at least the cavity 110C) can be covered. In addition, in the mold release film 20, a penetration hole 21 is formed at a position corresponding to the opening portion 131a of the pot 131 (a part located above the opening portion 131a of the pot 131). The penetration hole 21 is formed in a circular shape substantially the same as the shape of the opening portion 131a. More specifically, a diameter of the penetration hole 21 is formed to be slightly larger than the inner diameter of the pot 131 (the diameter of the opening portion 131a) and slightly smaller than an outer diameter of the pot 131.

After the mold release film 20 is arranged on an upper surface of the lower mold 110D, the mold release film 20 is sucked to the lower mold 110D by a suction mechanism 140. Specifically, the first suction portion 113, the second suction portion 114, and the third suction portion 115 are brought to negative pressure by the vacuum pump 116, and the mold release film 20 is sucked by each suction portion. Thereby, the mold release film 20 is arranged to follow the shape of the upper surface of the lower mold 110D as shown in FIG. 6. Particularly, because the part of the mold release film 20 on a periphery of the penetration hole 21 is sucked by the first suction portion 113, the mold release film 20 can be effectively suppressed from being peeled off from the lower mold 110D in the vicinity of the penetration hole 21 when the resin R is supplied from the pot 131 to the cavity 110C in the transfer step S50 described later. Thereby, when the resin R is supplied to the cavity 110C, the resin R can be suppressed from wrapping around the upper surface of the bottom surface member 111 of the lower mold 110D.

Additionally, in the embodiment, an example of using the mold release film 20 in which the penetration hole 21 is formed in advance has been shown, but the disclosure is not limited thereto. For example, the penetration hole 21 can also be formed after the mold release film 20 in which the penetration hole 21 is not formed is sucked to the lower mold 110D.

After the mold release film 20 is sucked to the lower mold 110D, the process proceeds from the film arrangement step S20 to the carrying-in step S30.

The carrying-in step S30 is a step of carrying the substrate 10 and the tablet resin 30 into the molding mold 110 and the resin injection mechanism 130.

Specifically, in the carrying-in step S30, the substrate 10 and the tablet resin 30 are carried into the molding mold 110 and the resin injection mechanism 130 by the predetermined conveyance device. As shown in FIG. 6, the substrate 10 is held at the upper mold 110U in a state that the surface 10a on which the semiconductor chip 11 is arranged is oriented downward. The tablet resin 30 is accommodated in the pot 131 via the opening portion 131a of the pot 131.

After the carrying-in of the substrate 10 and the tablet resin 30 is completed, the process proceeds from the carrying-in step S30 to the mold clamping step S40.

The mold clamping step S40 is a step of closing (mold-clamping) the molding mold 110 (the lower mold 110D and the upper mold 110U).

Specifically, in the mold clamping step S40, the lower mold 110D is raised toward the upper mold 110U by driving the elevating mechanism (not shown) of the mold clamping mechanism 120. When the lower mold 110D is raised to a predetermined position, as shown in FIG. 7, the contact surface 112a of the lower mold 110D comes into contact with the lower surface (the surface 10a) of the substrate 10, and the cavity 110C is blocked from above by the substrate 10. In addition, at this time, a lower surface of the semiconductor chip 11 arranged on the substrate 10 comes into contact with the bottom surface member 111 of the lower mold 110D.

After the mold clamping is completed, the process proceeds from the mold clamping step S40 to the transfer step S50.

The transfer step S50 is a step of transferring the resin R toward the cavity 110C.

Specifically, in the transfer step S50, the tablet resin 30 accommodated in the pot 131 is melted by a heating mechanism (not shown) arranged in the lower mold 110D. The melted tablet resin 30 (the resin R) is extruded upward from the pot 131 by the plunger 132. Thereby, as shown in FIG. 8, the resin R is directly supplied to the cavity 110C via the opening portion 131a of the pot 131. The resin R supplied to the cavity 110C flows in the cavity 110C from the central side to the outer peripheral side, and is filled in the cavity 110C.

At this time, because the resin R is directly supplied to the cavity 110C via the opening portion 131a having a relatively large inner diameter (an inner diameter substantially the same as an outer diameter of the plunger 132), the resin R can be made to flow into the cavity 110C without stagnation. Thereby, it becomes easy to fill the resin R into the cavity 110C, and an occurrence of defects related to resin filling such as voids, unfilling, and the like can be suppressed.

In addition, because the resin R can be directly supplied from the lower side of the cavity 110C, no runner is formed after the resin molding, and a yield of the resin material is high.

In addition, because the air in the cavity 110C is discharged from the outer peripheral part of the cavity 110C via the air discharge groove 112b (see FIG. 3) formed in the lower mold 110D, the flow of the resin R can be suppressed from being hindered by the air in the cavity 110C.

In addition, because the lower surface of the semiconductor chip 11 is in contact with the bottom surface member 111, the lower surface of the semiconductor chip 11 is not covered by the resin R. That is, the resin molding can be performed in a manner that the lower surface of the semiconductor chip 11 is revealed.

After the resin R is filled into the cavity 110C, the resin R is cured by waiting for a predetermined time.

After the resin R is cured, the process proceeds from the transfer step S50 to the mold opening step S60.

The mold opening step S60 is a step of opening (mold-opening) the molding mold 110 (the lower mold 110D and the upper mold 110U).

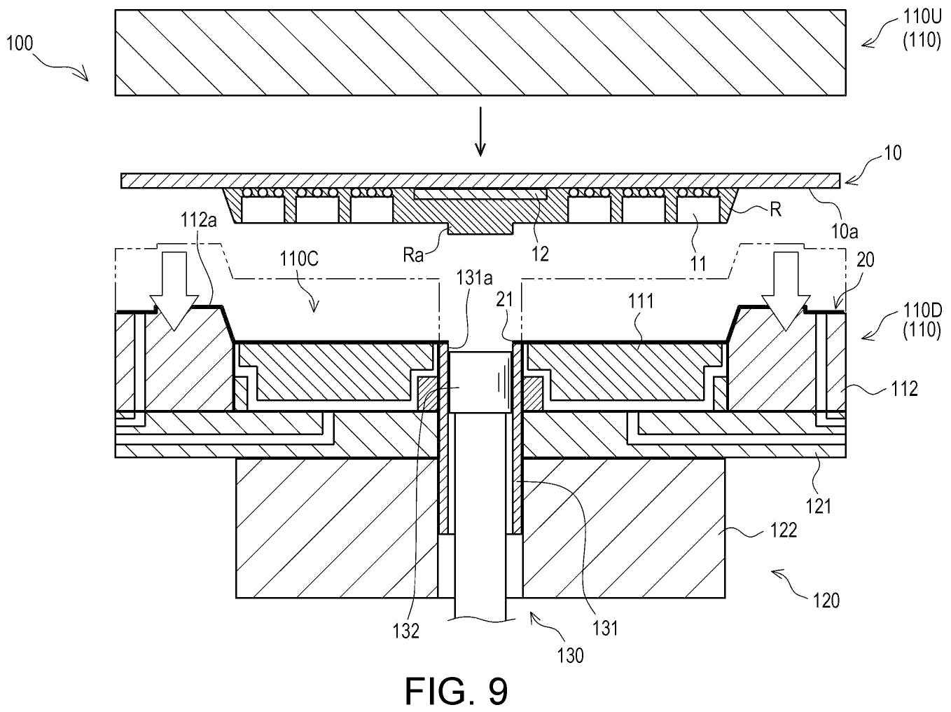

Specifically, in the mold opening step S60, the lower mold 110D is lowered so as to be separated from the upper mold 110U by driving the elevating mechanism (not shown) of the mold clamping mechanism 120. Thereby, as shown in FIG. 9, the contact surface 112a of the lower mold 110D is separated from the lower surface (the surface 10a) of the substrate 10.

After the mold opening is completed, the process proceeds from the mold opening step S60 to the carrying-out step S70.

The carrying-out step S70 is a step of carrying out the resin-sealed substrate 10 from the molding mold 110.

Specifically, in the carrying-out step S70, as shown in FIG. 9, the resin-sealed substrate 10 is detached from the upper mold 110U, and is carried out from the molding mold 110 by the predetermined conveyance device.

After the carrying-out of the substrate 10 is completed, the process proceeds from the carrying-out step S70 to the post-treatment step S80.

The post-treatment step S80 is a step of performing post-treatment of the substrate 10. Note that, the post-treatment step S80 is an embodiment of the removal step according to the disclosure.

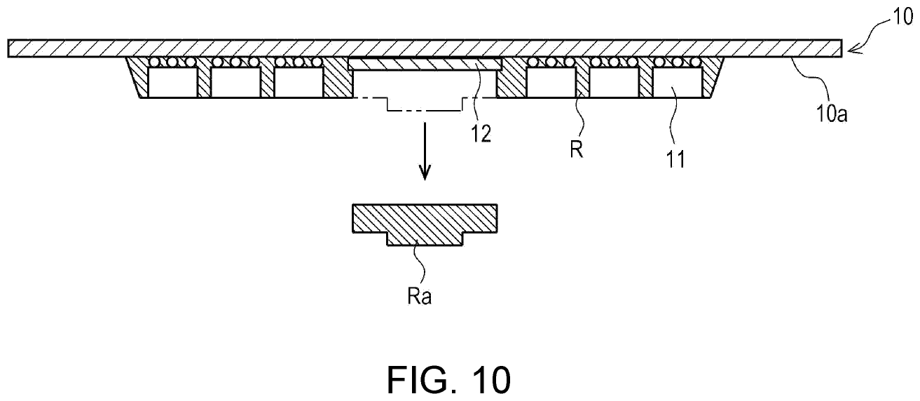

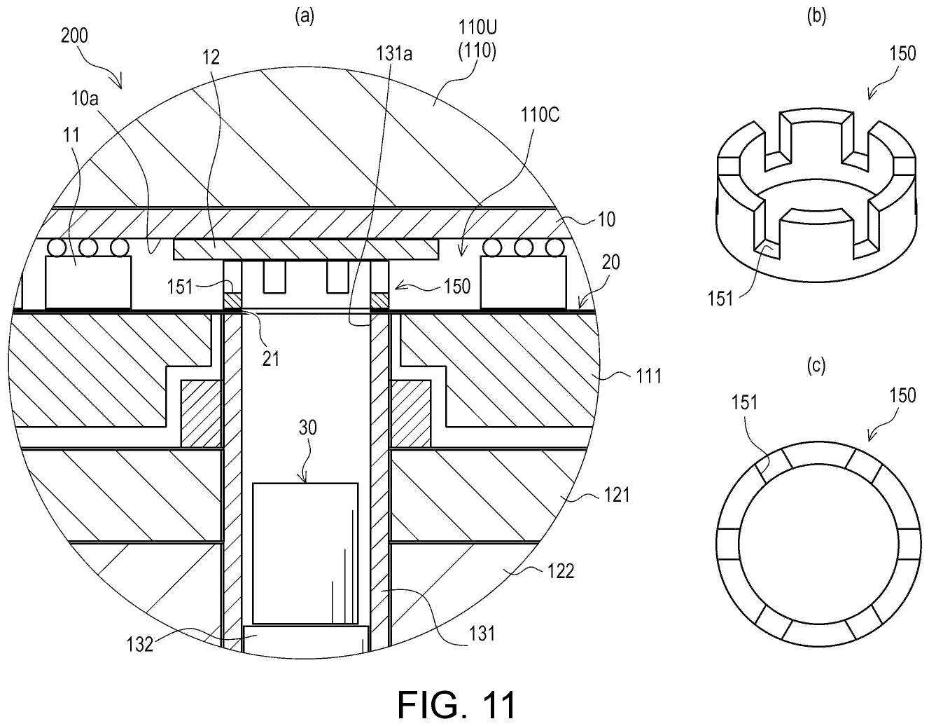

As shown in FIG. 9, an unnecessary resin Ra (cull) having an uneven shape corresponding to the shape of the pot 131 and the plunger 132 is formed in a part of the substrate 10 which faces the opening portion 131a of the pot 131. Therefore, in the post-treatment step S80, the unnecessary resin Ra formed at the center of the substrate 10 is removed as shown in FIG. 10. Because the mold release layer 12 is formed at the center of the substrate 10, the unnecessary resin Ra can be easily removed.

Additionally, as a method of removing the unnecessary resin Ra, various methods such as removal by laser processing, removal by grinding processing, removal by cutting, and the like can be adopted. For example, when the removal is performed by laser processing, the unnecessary resin Ra can be peeled off from the substrate 10 and removed by cutting the outer peripheral part of the unnecessary resin Ra into a circular shape. In addition, when the removal is performed by grinding processing, the unnecessary resin Ra can be removed by grinding. In addition, when the removal is performed by cutting, the unnecessary resin Ra can be broken and removed by grasping the protruding part of the unnecessary resin Ra and applying a force.

In the above manner, the substrate 10 (the resin molded product) which is resin-sealed in a state that a part (a lower surface) of the semiconductor chip 11 is revealed can be manufactured.

A resin molding apparatus 200 according to a second embodiment of the disclosure is described below with reference to FIG. 11.

The resin molding apparatus 200 according to the second embodiment is different from the resin molding apparatus 100 (see FIG. 7 and other figures) according to the first embodiment in that the resin molding apparatus 200 includes a pressing member 150. Therefore, the pressing member 150 is mainly described below.

The pressing member 150 presses the mold release film 20 along the molding mold 110 (the lower mold 110D). The pressing member 150 is formed in a ring shape (a cylindrical shape). An outer diameter of the pressing member 150 is formed to be substantially the same as the outer diameter of the pot 131 (slightly smaller than the outer diameter of the pot 131). An inner diameter of the pressing member 150 is formed to be substantially the same as the inner diameter of the pot 131 (slightly larger than the inner diameter of the pot 131). An axial width of the pressing member 150 is formed to be substantially the same as a vertical width of the cavity 110C (slightly smaller by the thickness of the mold release layer 12). A communication groove 151 is formed in the pressing member 150.

The communication groove 151 communicates an inner peripheral surface and an outer peripheral surface of the pressing member 150. The communication groove 151 is formed on an end surface (an upper end surface in FIG. 11) of the pressing member 150 in the axial direction. The communication groove 151 is formed to have an appropriate depth (a vertical width). A plurality of communication grooves 151 are radially formed centering on one point (the center of the pressing member 150) in a plan view. Note that, the communication groove 151 is an embodiment of the communication portion according to the disclosure.

The pressing member 150 is arranged in the cavity 110C after the mold release film 20 is arranged in the lower mold 110D (after the film arrangement step S20) and before the mold clamping is performed (before the mold clamping step S40). For example, the pressing member 150 is arranged in the cavity 110C after the substrate 10 and the tablet resin 30 are carried into the molding mold 110 in the carrying-in step S30. At this time, the pressing member 150 is arranged above the pot 131 as shown in (a) of FIG. 11. Thereby, the pressing member 150 is arranged to surround the periphery of the penetration hole 21 of the mold release film 20. In addition, the pressing member 150 is arranged to sandwich the mold release film 20 together with the pot 131 from above and below.

After the pressing member 150 is arranged in the cavity 110C, the pressing member 150 is mold-clamped in the mold clamping step S40, and thereby an upper surface of the pressing member 150 comes into contact with the mold release layer 12 formed on the substrate 10. In this way, the pressing member 150 is pressed from above by the substrate 10 (the mold release layer 12) in the state of being mold-clamped, and thus the pressing member 150 is held at the upper part of the pot 131.

By arranging the pressing member 150 in this way, the periphery of the penetration hole 21 of the mold release film 20 can be pressed so as not to be peeled off from the lower mold 110D. Thereby, the resin R can be suppressed from invading between the mold release film 20 and the upper surface of the lower mold 110D when the resin R is supplied from the pot 131 to the cavity 110C in the transfer step S50.

In addition, thereafter, the resin R supplied into the cavity 110C via the opening portion 131a flows out from an inner peripheral side to an outer peripheral side of the pressing member 150. At this time, the resin R is distributed substantially evenly by the communication groove 151 radially formed in the pressing member 150 and flows in the cavity 110C from the central side to the outer peripheral side. By arranging the flow of the resin R by the pressing member 150 in this way, the occurrence of defects related to resin filling such as voids, unfilling, and the like can be suppressed.

As described above, the resin molding apparatus 100 or 200 according to the embodiment includes:

the molding mold 110 which forms the cavity 110C;
the pot 131 which is arranged in the molding mold 110 and is capable of accommodating the resin material, and in which the opening portion 131a opening directly to the cavity 110C is formed; and
the plunger 132 which is arranged to be slidable in the pot 131, and transfers the resin material accommodated in the pot 131 toward the cavity 110C via the opening portion 131a by extruding the resin material, wherein
the inner diameter of the opening portion 131a is formed to be the same as the outer diameter of the plunger 132 or larger than the outer diameter of the plunger.

By configuring in this way, the occurrence of defects related to resin filling can be suppressed. That is, by ensuring that the inner diameter of the opening portion 131a is at least as large as the outer diameter of the plunger 132, the resin material in the pot 131 becomes easy to flow into the cavity 110C. Thereby, the occurrence of defects related to resin filling such as voids, unfilling, and the like can be suppressed.

In addition, the molding mold 110 includes the first suction portion 113 (the suction portion) which sucks a part of the mold release film 20 on the periphery of the penetration hole 21, wherein in the mold release film 20, the penetration hole 21 is formed at a position facing the opening portion 131a.

By configuring in this way, the occurrence of defects related to resin filling can be suppressed. That is, it is possible to suppress the resin material from entering between the mold release film 20 and the molding mold 110 around the opening portion 131a, resulting in molding defects.

In addition, the resin molding apparatus 200 according to the embodiment further includes the pressing member 150 which presses a part or all of the periphery of the penetration hole 21 in the mold release film 20 so as not to be peeled off from the molding mold 110.

By configuring in this way, the occurrence of defects related to resin filling can be suppressed. That is, it is possible to suppress the resin material from entering between the mold release film 20 and the molding mold 110 around the opening portion 131a, resulting in molding defects.

In addition, the pressing member 150 includes the radial communication groove 151 (the communication portion) which is formed in a ring shape surrounding the periphery of the penetration hole 21 and communicates the inner peripheral surface and the outer peripheral surface.

By configuring in this way, the occurrence of defects related to resin filling can be suppressed. That is, the resin material transferred toward the cavity 110C via the opening portion 131a is radially distributed and guided by the communication groove 151, and thereby the bias of the resin material in the flow direction can be suppressed. Thereby, the occurrence of defects related to resin filling such as voids, unfilling, and the like can be suppressed.

In addition, the pot 131 is arranged at the central part of the cavity 110C.

By configuring in this way, the occurrence of defects related to resin filling can be suppressed. That is, it becomes easy to uniformly supply the resin material to the entire cavity 110C, and the occurrence of defects related to resin filling such as voids, unfilling, and the like can be suppressed. In addition, because the resin material is filled in a manner of expanding from the central part toward the outer side of the cavity 110C, the flow distance of the resin material becomes relatively short, and the molding time can be shortened.

In addition, the molding mold 110 includes the air discharge groove 112b (the air discharge portion) capable of discharging the air in the cavity 110C from the outer peripheral part of the cavity 110C to the exterior.

By configuring in this way, the occurrence of defects related to resin filling can be suppressed. That is, by discharging the air from the outer peripheral part of the cavity 110C, the resin material becomes easy to flow into the cavity 110C from the central part of the cavity 110C. Thereby, the occurrence of defects related to resin filling such as voids, unfilling, and the like can be suppressed.

In addition, the manufacturing method of a resin molded product according to the embodiment is for manufacturing a resin molded product by using the resin molding apparatus 100 or 200.

By configuring in this way, the occurrence of defects related to resin filling can be suppressed.

In addition, the manufacturing method of a resin molded product according to the embodiment includes:

the mold clamping step S40, in which the mold clamping is performed on the molding mold 110 forming the cavity 110C after the substrate 10 is conveyed to the molding mold 110 and the resin material is conveyed to the pot 131 in which the opening portion 131a opening directly to the cavity 110C is formed; and
the transfer step S50, in which the resin material accommodated in the pot 131 is transferred toward the cavity 110C via the opening portion 131a by extruding the resin material with the plunger 132 after the mold clamping step S40, wherein
in the transfer step S50, the resin material is transferred via the opening portion 131a having the inner diameter which is the same as the outer diameter of the plunger 132 or larger than the outer diameter of the plunger 132.

By configuring in this way, the occurrence of defects can be suppressed. That is, by ensuring that the inner diameter of the opening portion 131a is at least as large as the outer diameter of the plunger 132, the resin material in the pot 131 becomes easy to flow into the cavity 110C. Thereby, the occurrence of defects such as voids, unfilling, and the like can be suppressed.

In addition, the manufacturing method of a resin molded product according to the embodiment further includes the post-treatment step S80 (the removal step) in which the unnecessary resin Ra (the unnecessary part) formed in the part of the substrate 10 which faces the opening portion 131a is removed after the transfer step S50.

By configuring in this way, the resin molded product from which the unnecessary part is removed can be obtained.

In addition, the manufacturing method of a resin molded product according to the embodiment further includes the preparation step S10 (the mold release layer forming step) in which the mold release layer 12 is formed in the part of the substrate 10 which faces the opening portion 131a prior to the mold clamping step S40.

By configuring in this way, the unnecessary part can be easily removed. That is, because the unnecessary part formed in the part facing the opening portion 131a becomes easy to be peeled off from the substrate 10, the unnecessary part can be easily removed from the substrate 10.

In addition, the manufacturing method of a resin molded product according to the embodiment further includes the film arrangement step S20 in which the mold release film 20 in which the penetration hole 21 is formed at a position corresponding to the opening portion 131a is arranged in the molding mold 110 prior to the mold clamping step S40.

By configuring in this way, the occurrence of defects related to resin filling can be suppressed. That is, by using the mold release film 20 in which the penetration hole 21 is formed, it is possible to prevent the molded article from adhering to the molding mold 110 without hindering the flow of the resin material into the cavity 110C.

Although the embodiments of the disclosure are described above, the disclosure is not limited to the above-described embodiments, and appropriate changes can be made within the scope of the technical idea of the invention described in the claims.

For example, in the embodiment, the resin molding apparatus 100 using the circular cavity 110C and the circular substrate 10 is exemplified, but the shapes of the cavity 110C and the substrate 10 are not limited thereto. For example, a rectangular substrate 10 can also be used, and in this case, the shape of the cavity 110C can also be formed in a rectangular shape in a plan view according to the shape of the substrate 10.

In addition, in the embodiment, an example is shown in which the mold release film is used as the mold release layer 12 formed on the substrate 10, but the disclosure is not limited thereto, and various materials (for example, metal materials and the like) can also be used. In addition, the mold release layer 12 can also be formed by directly coating the substrate 10.

In addition, in the embodiment, the inner diameter of the opening portion 131a of the pot 131 is set to be the same as the outer diameter of the plunger 132, but the disclosure is not limited thereto. For example, the inner diameter of the pot 131 can also be formed to be gradually increased toward the upper end (in a tapered shape), and the inner diameter of the opening portion 131a can also be formed to be larger than the outer diameter of the plunger 132. Thereby, the resin R can more easily flow into the cavity 110C.

In addition, in the embodiment, an example is shown in which the pot 131 is arranged at the central part of the cavity 110C, but the disclosure is not limited thereto, and the pot 131 can be arranged at any position in the cavity 110C. In addition, a plurality of pots 131 can also be arranged.

In addition, in the embodiment (the second embodiment), the pressing member 150 formed in a cylindrical shape is exemplified, but the disclosure is not limited thereto, and the pressing member 150 can be formed in any shape as long as at least a part of the mold release film 20 on the periphery of the penetration hole 21 can be pressed. However, from the viewpoint of preventing the mold release film 20 from being peeled off from the vicinity of the penetration hole 21, the pressing member 150 is preferably formed in such a tubular shape that the entire periphery of the penetration hole 21 can be pressed (a tubular shape surrounding the penetration hole 21).

In addition, in the embodiment (the second embodiment), an example is shown in which the groove-shaped communication portion (the communication groove 151) is formed on the upper surface of the pressing member 150, but the disclosure is not limited thereto. For example, it is also possible to form a penetration hole which penetrates a vertical midway part of the pressing member 150 in the radial direction of the pressing member 150, and communicate the inner peripheral surface and the outer peripheral surface of the pressing member 150 by this penetration hole.

In addition, in the embodiment, an example is shown in which the tablet-shaped resin material (the tablet resin 30) is used, but the disclosure is not limited thereto. That is, as the resin material, not only the tablet-shaped resin material but also a resin material in an arbitrary form such as granule, powder, liquid, or the like can be used.

In addition, the manufacturing method of a resin molded product (sequences of the steps, work contents and procedures in each step, and the like) exemplified in the embodiment is an example, and can be arbitrarily changed.

In addition, in the embodiment, an example is shown in which the mold release film 20 in which the penetration hole 21 is formed in advance is arranged in the molding mold 110 in the film arrangement step S20, but the disclosure is not limited thereto. For example, the penetration hole 21 may also be formed at a position corresponding to the opening portion 131a of the pot 131 after the mold release film 20 is arranged in the molding mold 110.

In addition, in the embodiment, an example is shown in which the lower mold 110D includes the bottom surface member 111, the side surface member 112, and the like, and the cavity 110C is formed by the bottom surface member 111 and the side surface member 112, but the disclosure is not limited thereto. For example, the upper surface of the lower mold 110D composed of one member may be processed to form the cavity 110C.

In addition, the resin molding apparatus 100 or 200 exemplified in the embodiment is an example, and various mechanisms not shown in the embodiment may be included. For example, the resin molding apparatus 100 or 200 may also include a substrate conveyance module which performs conveyance of the substrate 10 (carrying-in to the molding mold 110 and carrying-out from the molding mold 110), a resin supply module which supplies the resin (the tablet resin 30) to the resin injection mechanism 130, and the like.

What is claimed is:

1. A resin molding apparatus, comprising:
a molding mold which forms a cavity;
a pot which is arranged in the molding mold and is capable of accommodating a resin material, and in which an opening portion opening directly to the cavity is formed; and
a plunger which is arranged to be slidable in the pot, and transfers a resin material accommodated in the pot toward the cavity via the opening portion by extruding the resin material, wherein
an inner diameter of the opening portion is formed to be the same as an outer diameter of the plunger or larger than the outer diameter of the plunger.

2. The resin molding apparatus according to claim 1, wherein
the molding mold comprises a suction portion which sucks a part of a mold release film on a periphery of a penetration hole, wherein in the mold release film, the penetration hole is formed at a position facing the opening portion.

3. The resin molding apparatus according to claim 2, further comprising a pressing member which presses a part or all of the periphery of the penetration hole in the mold release film so as not to be peeled off from the molding mold.

4. The resin molding apparatus according to claim 3, wherein
the pressing member comprises a radial communication portion which is formed in a ring shape surrounding the periphery of the penetration hole and communicates an inner peripheral surface and an outer peripheral surface.

5. The resin molding apparatus according to claim 1, wherein
the pot is arranged in a central part of the cavity.

6. The resin molding apparatus according to claim 5, wherein
the molding mold comprises an air discharge portion capable of discharging air in the cavity from an outer peripheral part of the cavity to the exterior.

7. A manufacturing method of a resin molded product, for manufacturing a resin molded product by using the resin molding apparatus according to claim 1.

8. A manufacturing method of a resin molded product, comprising:
a mold clamping step, in which mold clamping is performed on a molding mold forming a cavity after a substrate is conveyed to the molding mold and a resin material is conveyed to a pot in which an opening portion opening directly to the cavity is formed; and
a transfer step, in which a resin material accommodated in the pot is transferred toward the cavity via the opening portion by extruding the resin material with a plunger after the mold clamping step, wherein
in the transfer step, the resin material is transferred via the opening portion having an inner diameter which is the same as an outer diameter of the plunger or larger than the outer diameter of the plunger.

9. The manufacturing method of a resin molded product according to claim 8, further comprising
a removal step, in which an unnecessary part formed in a part of the substrate which faces the opening portion is removed after the transfer step.

10. The manufacturing method of a resin molded product according to claim 8, further comprising
a mold release layer forming step, in which a mold release layer is formed in the part of the substrate which faces the opening portion prior to the mold clamping step.

11. The manufacturing method of a resin molded product according to claim 8, further comprising
a film arrangement step, in which a mold release film in which a penetration hole is formed at a position corresponding to the opening portion is arranged in the molding mold prior to the mold clamping step.
